(19) United States
(12) Patent Application Publication
(10) Pub. No.: US 2024/0364121 A1
(43) Pub. Date: Oct. 31, 2024

(54) BATTERY MANAGEMENT SYSTEM AND OPERATION METHOD THEREOF

(71) Applicant: MOCURA TEC, Seongnam-si, Gyeonggi-do (KR)

(72) Inventor: Gi Tek PARK, Seoul (KR)

(73) Assignee: MOCURA TEC, Seongnam-si, Gyeonggi-do (KR)

(21) Appl. No.: 18/579,684

(22) PCT Filed: Sep. 1, 2021
(86) PCT No.: PCT/KR2021/011751

§ 371 Date: Jan. 16, 2024

(30) Foreign Application Priority Data
Jul. 16, 2021 (KR) 10-2021-0093816

(51) Int. Cl. H02J 7/00; H01M 10/42; H01M 10/6551

(52) U.S. Cl. CPC H02J 7/0016; H01M 10/425; H01M 10/6551; H02J 7/007182; H01M 2010/4271

(57) ABSTRACT

A battery management system according to an exemplary embodiment of the present disclosure may comprise: a first bypass transistor which includes a first terminal directly electrically connected to a positive electrode of a battery cell and a second terminal directly electrically connected to a negative electrode of the battery cell, and bypasses the current of the battery cell on the basis of a bypass signal so as to receive an input; and a heat sink formed adjacent to the first bypass transistor in order to cool the first bypass transistor by removing the heat generated therein.

### CROSS-REFERENCE TO RELATED APPLICATIONS

The present application is a national stage entry of International Patent Application No. PCT/KR2021/011751, filed on Sep. 1, 2021, which is based upon and claims the benefit of priority to Korean Patent Application No. 10-2021-0093816 filed on Jul. 16, 2021. The disclosures of the above-listed applications are hereby incorporated by reference herein in their entirety.

### TECHNICAL FIELD

The technical idea of the present disclosure relates to a battery management system and an operation method thereof, and more particularly, to a battery management system including a high-current bypass module that operates according to a time-divided control signal, and an operation method thereof.

### BACKGROUND ART

With the development of electronic technology, various types of electronic devices are being used. Electronic devices that operate by driving batteries may include, for example, mobile electronic devices such as smartphones, electric vehicles, and even emergency power devices (e.g., an uninterruptable power supply (UPS), an energy storage system (ESS), and the like) in server rooms or power plants. As the power consumption of the electronic device increases, there has been an increase in battery capacity, and as dependence on batteries increases, the number of charging and discharging cycles increases, exposing the battery to harsh environments, including sudden temperature changes. Accordingly, battery-related fire accidents occur frequently, and a malfunction problem of an electronic device due to battery failures has emerged.

### DISCLOSURE

### Technical Problem

The problem to be solved by the technical idea of the present disclosure is to solve cell unbalancing, which occurs due to the accumulation of charge and discharge cycles, by controlling cell charging based on cell temperature through a time-divided bypass control signal and a bypass module, and furthermore, to prevent a fire accident caused by battery-related devices.

### Technical Solution

One aspect of the present disclosure provides a battery management system including a first bypass transistor including a first terminal electrically and directly connected to a positive electrode of a battery cell and a second terminal electrically and directly connected to a negative electrode of the battery cell, and configured to receive an input by bypassing a current of the battery cell on the basis of a bypass signal, and a heat sink formed adjacent to the first bypass transistor to cool heat generated in the first bypass transistor.

Further, the first bypass transistor may include a first conductor formed to directly connect the first terminal to the positive electrode of the battery cell without resistance, and a second conductor formed to directly connect the second terminal to the negative electrode of the battery cell without resistance.

Further, the first bypass transistor may include a bipolar junction transistor (BJT).

Meanwhile, the heat sink may be located on upper portions of a plurality of first bypass transistors included in a battery block and shared by the plurality of first bypass transistors.

Further, the heat sink may cool the generated heat through a time-divided control signal having a logic high or logic low state input to the first bypass transistor.

Meanwhile, the battery management system may further include a control logic configured to detect a heat generation amount of the heat sink, and block all charging currents connected in series in the battery management system when the heat generation amount exceeds a reference value.

Another aspect of the present disclosure provides a battery management device including a heat sink formed to correspond to at least some of a plurality of battery cells, and a bypass module configured to conduct a bypass current, which bypasses the battery cells, during charging of the at least some of the plurality of battery cells, and amplify a magnitude of the bypass current in response to a bypass signal in a logic high state.

Further, the bypass module may further include a switch module that is turned on in response to the bypass signal in the logic high state, and a first bypass transistor configured to form a bypass current path in response to the switch module being turned on.

Further, the battery management device may further include a second bypass transistor configured to receive a current that is input to the bypass module, and amplify a magnitude of the current in response to the first bypass transistor being turned on.

Further, the second bypass transistor may be a PNP transistor, and the switch module and the first bypass transistor may be NPN transistors.

Meanwhile, the switch module may be a photocoupler that physically separates the bypass current path from a current path from which the bypass signal is received.

Meanwhile, the battery management device may further include a control logic configured to output a first bypass signal to a first bypass module corresponding to a first battery cell, and to output a second bypass signal in a state inverted from the first bypass signal to a second bypass module corresponding to a second battery cell adjacent to the first battery cell.

Still another aspect of the present disclosure provides a battery management device including a heat sink formed to correspond to at least some of a plurality of battery cells, a bypass module configured to conduct a bypass current, which bypasses the battery cells, during charging of the at least some of the plurality of battery cells on the basis of a bypass signal, and a control logic configured to output a first bypass signal to a first bypass module corresponding to a first battery cell, and to output a second bypass signal in a state inverted from the first bypass signal to a second bypass module corresponding to a second battery cell adjacent to the first battery cell.

Yet another aspect of the present disclosure provides a battery management device including a control logic configured to bypass a charging current prior to entering full charge when a charging voltage of a first battery cell in a first battery block is higher than a charging voltage of a second battery cell in a second battery block connected in series to the first battery block to prevent thermal runaway of a heat sink included in the first battery block and shared by a plurality of battery cells included in the first battery block, wherein the thermal runaway is caused by simultaneously heating the plurality of battery cells when the plurality of battery cells included in the first battery block simultaneously reach a full-charge voltage.

Further, when the first battery cell, the second battery cell, and the plurality of battery cells are lithium-ion battery cells, the full-charge voltage may be 4.0 V to 4.4 V, when the first battery cell, the second battery cell, and the plurality of battery cells are lithium-iron-phosphate battery cells, the full-charge voltage may be 3.4 V to 3.8 V, and the control logic may operate the plurality of battery cells normally by preventing the thermal runaway caused by the simultaneous heating.

### Advantageous Effects

In a battery management device according to an exemplary embodiment of the present disclosure, a bypass transistor and a time-divided bypass signal that controls the bypass transistor are provided to prevent overheating of a battery cell or a transistor corresponding to the battery cell, so that a lifespan of a battery can be extended, and a voltage applied to the battery cell can be inhibited from rising beyond a limit by controlling the bypass current, so that an unbalancing problem can be eliminated.

### DESCRIPTION OF DRAWINGS

FIG. 1 is a block diagram for describing a battery management device according to an exemplary embodiment of the present disclosure.

FIG. 2 is a circuit diagram for describing a battery block according to an exemplary embodiment of the present disclosure.

FIG. 3 is a circuit diagram for describing a bypass module according to an exemplary embodiment of the present disclosure.

FIG. 4A is a circuit diagram for describing a bypass module according to another embodiment of the present disclosure, and FIG. 4B is a circuit diagram for describing a bypass module according to still another embodiment of the present disclosure.

FIG. 5 is a circuit diagram for describing the battery block and the bypass module according to the exemplary embodiment of the present disclosure.

FIG. 6 is a circuit diagram for describing a cell resistor according to a comparative example.

FIGS. 7 to 9 are diagrams for describing bypass signals according to an exemplary embodiment of the present disclosure.

FIG. 10 is a diagram for describing bypass signals according to an exemplary embodiment of the present disclosure.

FIG. 11 is a graph for describing a depth of discharge (DoD) cycle according to an exemplary embodiment of the present disclosure.

FIG. 12 is a graph for describing a variation of a life cycle according to an exemplary embodiment of the present disclosure.

### MODES OF THE INVENTION

Hereinafter, embodiments of the present invention will be described in detail with reference to the accompanying drawings.

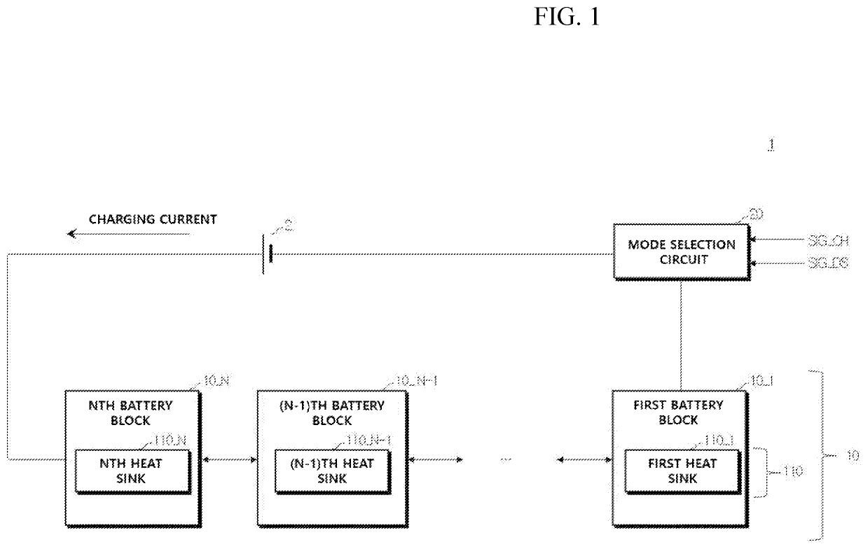

FIG. 1 is a block diagram for describing a battery management device according to an exemplary embodiment of the present disclosure.

Referring to FIG. 1, a battery management system may include a battery management device 1 and a charging power source 2, and the battery management device 1 may include a plurality of battery blocks 10_1 to 10_N including individual battery blocks 10 and a mode selection circuit 20. The charging power source 2 may supply power to charge a battery cell included in each of the battery blocks 10.

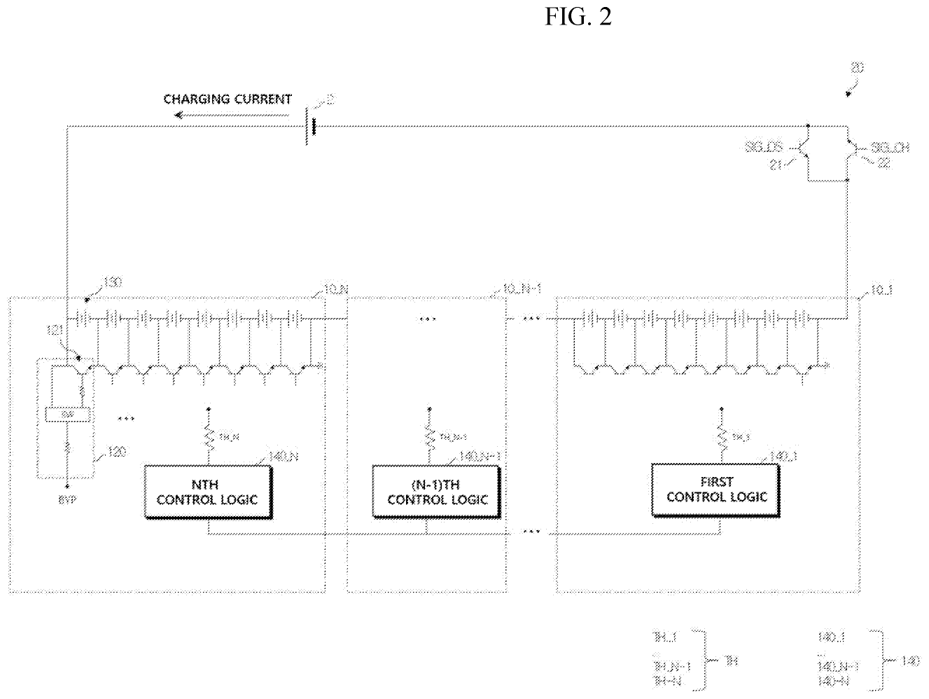

The battery block 10 may include a heat sink 110 and the battery cell. Each battery block 10 may include a plurality of battery cells, and may include the heat sink 110 corresponding to the plurality of battery cells. As an example, the heat sink 110 corresponding to eight battery cells may be included, and as another example, the heat sink 110 corresponding to bypass switches of eight battery cells may be included. This will be described below with reference to FIG. 2.

The mode selection circuit 20 may receive a charge signal SIG_CH and a discharge signal SIG_DS. When the mode selection circuit 20 receives the charge signal SIG_CH, the mode selection circuit 20 may form a current path in a direction in which a charging current flows. On the contrary, when the mode selection circuit 20 receives the discharge signal SIG_DS, the mode selection circuit 20 may form a current path in a direction opposite to the direction in which the charging current flows to allow at least some of the plurality of battery blocks 10_1 to 10_N to supply power to a load (not shown).

According to the exemplary embodiment of the present disclosure, the plurality of battery blocks 10_1 to 10_N may be connected in series with each other to perform charging and discharging. For example, in the charging power source 2, the charging current may be output from a positive electrode. The charging current may be conducted from an Nth battery block 10_N to a first battery block 10_1.

In this case, an unbalancing phenomenon may occur in which voltages between the plurality of battery cells included in each of the plurality of battery blocks 10_1 to 10_N or voltages between the plurality of battery blocks 10_1 to 10_N are unbalanced.

Accordingly, overheating, destruction, or deterioration of the battery cells may occur, and a bypass module to be described below in FIG. 2 may uniformly maintain the voltages between the battery cells.

FIG. 2 is a circuit diagram for describing a battery block according to an exemplary embodiment of the present disclosure. Hereinafter, a description will be given with also reference to the reference numerals of FIG. 1.

Referring to FIG. 2, the battery block 10 may further include bypass modules 120, battery cells 130, a control logic 140, and a thermometer TH. In addition, the plurality of battery blocks 10_1 to 10_N may each include a plurality of bypass modules 120 and a plurality of battery cells 130, and may include a plurality of control logics 140_1 to 140_N and a plurality of thermometers TH_1 to TH_N.

According to the exemplary embodiment of the present disclosure, each battery block 10 may include eight battery cells 130, and the number of the plurality of battery blocks 10_1 to 10_N may be 13 (i.e., N=13). In this case, the total number of the battery cells 130 included in the battery management device 1 may be 8*13=104. For example, a rated voltage of the battery cell 130 may be 3.7 V, in which case, a total rated voltage of 104 series battery cells 130 may be 384.8 V. In addition, a full-charge (i.e., fully charged) voltage of the battery cell 130 may be 4.2 V, in which case, a total full-charge voltage of the 104 series battery cells 130 may be 438.8 V.

The positive electrode (positive pole) of the charging power source 2 may be connected to a positive electrode of an Nth battery cell 130, and a negative electrode (negative pole) of the charging power source 2 may be connected to a negative electrode of a first battery cell 130. In this case, the charging current may charge the battery cells 130 while being conducted from the Nth battery block 10_N to the first battery block 10_1. Thereafter, the charging current may be output to the negative electrode of the charging power source 2 via a second mode selection transistor 22 that is turned on by receiving the charge signal SIG_CH in a logic high state. At this time, the discharge signal SIG_DS has a state opposite to the charge signal SIG_CH and thus may be in a logic low state, and a first mode selection transistor 21 may be turned off and the second mode selection transistor 22 may be turned on.

Meanwhile, the control logic 140 may generate and output the charge signal SIG_CH and the discharge signal SIG_DS. As an example, a first control logic 140_1 may operate as a master control logic, and may output the charge signal SIG_CH and the discharge signal SIG_DS. As another example, a separate master control logic may output the charge signal SIG_CH and the discharge signal SIG_DS.

The control logic 140 may detect a heat generation amount of a heat sink 110, and when the heat generation amount exceeds a reference value, the control logic 140 may control to cut off all charging currents connected in series in the battery management system. For example, the control logic 140 may output the discharge signal SIG_DS in a logic high state to cut off the charging current.

The plurality of control logics 140_1 to 140_N may communicate with each other. For example, the first control logic 140_1 may serve as the master control logic. In this case, the first control logic 140_1 may receive a value related to a total current magnitude during charging or discharging. Bypass signals BYP may be generated and output by controlling each of the plurality of control logics 140_1 to 140_N according to the received current magnitude. For example, in response to an instruction based on 485 communication of the first control logic 140_1 (e.g., including data such as a current magnitude, temperature information, or the like), an Nth control logic 140_N may generate the bypass signals BYP used in the Nth battery block 10_N.

According to the exemplary embodiment of the present disclosure, 104 series-connected battery cells 130 may be configured as blocks of eight, resulting in 13 blocks, such that the full-charge voltage of each battery block 10 may be 8 series*4.2V=33.6 V. Since the maximum operating voltage of an integrated circuit (IC) of an external control unit and/or the control logic 140 of the battery management device 1 is limited, the eight series-connected battery cells 130 may be configured as a block, and for a voltage resolution of the eight battery cells 130 in the same battery block 10, a 13-bit analog digital converter (ADC) may have a resolution variation of 33.6 V/8,112 (13 bits)=4.142 mV. When 16 series-connected battery cells 130 are provided, the battery cells 130 have an error of 67.2 V/8,112=8.284 mV.

In this case, in the case of the error of 8.28 mV, 4.20 V may become 4.21 V, which is the next step number, due to the error, and thus the error should be 4.142 mV which allows to secure 4.20 V.

According to the exemplary embodiment of the present disclosure, the bypass module 120 may control so that the charging current is not input to the battery cell 130 in response to the bypass signal BYP. During charging of at least some of the plurality of battery cells 130, the bypass module 120 may amplify the magnitude of the bypass current by conducting a bypass current, which bypasses the battery cell 130, in response to the bypass signal BYP in a logic high state.

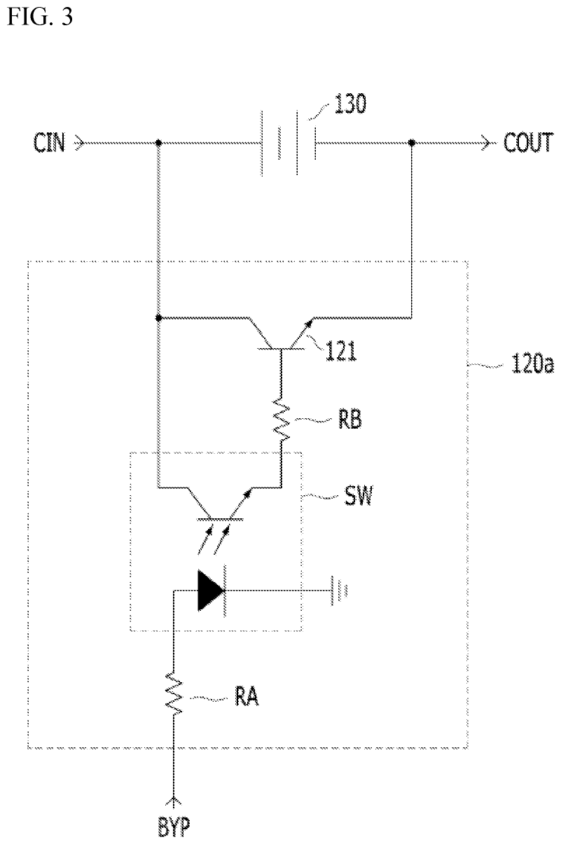

Specifically, the bypass module 120 may generate a bypass path, which bypasses the battery cell 130, when receiving the bypass signal BYP in a logic high state. The bypass path passes through a first bypass transistor 121 of the bypass module 120, and may not pass through the battery cell 130. In this case, a current flowing through the first bypass transistor 121 may be referred to as the bypass current, and the bypass current may be referred to as being conducted through the bypass path. This will be described in detail with reference to FIGS. 3 to 5.

The bypass module 120 may include a switch module SW. The switch module SW may be an element that is turned on in response to the bypass signal BYP of in a logic high state to directly generate the bypass path and may include, for example, a photocoupler. In addition, the bypass signal BYP may be a signal input to the bypass modules 120 corresponding to the respective battery cells 130. For example, the battery management device 1 may include 104 bypass modules 120 to respectively correspond to the 104 battery cells 130. The 104 bypass signals BYP may be input to control the respective 104 bypass modules 120.

A thermometer TH may sense a temperature of the bypass transistor 121. The thermometer TH may transmit a sensed temperature value to the control logic 140. The control logic 140 may generate the bypass signal BYP on the basis of the received temperature value.

Meanwhile, a charging voltage of the first battery cell in the first battery block 10_1 of the battery management device 1 may be higher than a charging voltage of a second battery cell in a second battery block connected in series to the first battery block 10_1. In this case, the control logic 140 may bypass the charging current prior to entering full charge to prevent thermal runaway of the heat sink 110 included in the first battery block 10_1 and shared by the plurality of battery cells included in the first battery block 10_1, wherein the thermal runaway is caused by simultaneously heating the plurality of battery cells when the plurality of battery cells included in the first battery block 10_1 simultaneously reach the full-charge voltage.

At this time, when the aforementioned battery cells are lithium-ion battery cells, the full-charge voltage may be 4.0 V to 4.4 V, and preferably 4.2 V, and when the aforementioned battery cells are lithium-iron-phosphate battery cells, the full-charge voltage may be 3.4 V to 3.8V, and preferably 3.6 V.

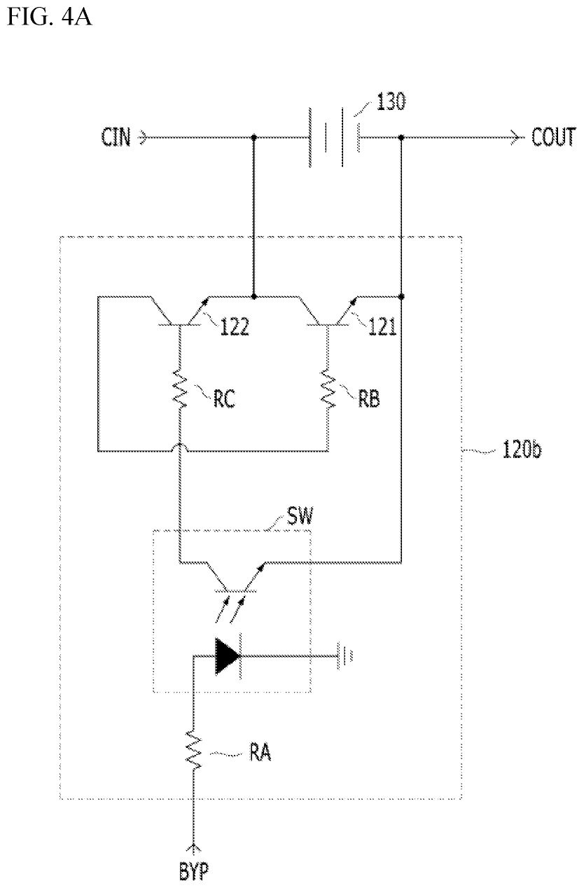

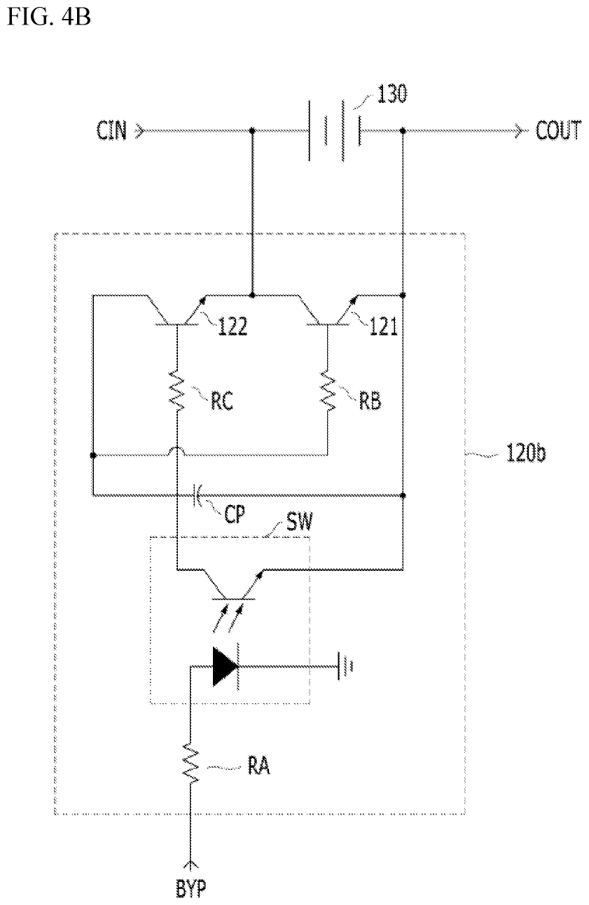

FIG. 3 is a circuit diagram for describing a bypass module according to one embodiment of the present disclosure, FIG. 4A is a circuit diagram for describing a bypass module according to another embodiment of the present disclosure, and FIG. 4B is a circuit diagram for describing a bypass module according to still another embodiment of the present disclosure. Hereinafter, a description will be given with also reference to the reference numerals of FIGS. 1 and 2.

Referring to FIGS. 3, 4A, and 4B, the bypass module 120 may include a first bypass module 120a and a second bypass module 120b. In other words, at least some of the plurality of battery blocks 10_1 to 10_N may include the first bypass module 120a, and at least another some of the plurality of battery blocks 10_1 to 10_N may include the second bypass module 120b.

Referring to FIG. 3, the first bypass module 120a may include an input resistor RA, a first bypass resistor RB, a first bypass transistor 121, and a switch module SW.

The first bypass transistor 121 may include a first terminal (e.g., a collector terminal) electrically and directly connected to the positive electrode of the battery cell 130 and a second terminal (e.g., an emitter terminal) electrically and directly connected to the negative electrode of the battery cell 130. In addition, the first bypass transistor 121 may bypass the current flowing through the battery cell 130 on the basis of the bypass signal BYP to receive an input.

In this case, the heat sink 110 may be formed adjacent to the first bypass transistor 121 to cool heat generated in the first bypass transistor 121.

Meanwhile, the first bypass transistor 121 may include a first conductor formed to directly connect the first terminal to the positive electrode of the battery cell 130 without resistance, and a second conductor formed to directly connect the second terminal to the negative electrode of the battery cell 130 without resistance. The conductor may include, for example, a conducting wire. That is, a separate resistor is not disposed on the conducting wire through which the battery cell 130 is connected to the first bypass transistor 121.

The first bypass transistor 121 may include a bi-polar junction transistor (BJT). For example, when the first bypass transistor 121 is implemented as a BJT, a base resistance value of the first bypass transistor 121 may be adjusted to control a current of 5 A. That is, when a current of 0.05 A is input, the base resistance value is adjusted to control a collector-emitter current to 5 A. As described above, the first bypass transistor 121 is implemented as a BJT, and a current amplification rate may be adjusted using the base resistance.

The switch module SW may receive the bypass signal BYP from an input end through the input resistor RA. Based on the bypass signal BYP in a logic high state, the switch module SW may conduct an output end current. That is, the switch module SW may be turned on.

The switch module SW may be implemented as a photocoupler. This is to stabilize the charging current by physically separating (disconnecting) a current path of a circuit to which the bypass signal BYP is input from a current path through which the charging current bypasses.

As the switch module SW is turned on, the bypass transistor 121 may be turned on. Specifically, when the switch module SW is turned on and an output end thereof is electrically connected, an input current CIN may flow from the first terminal to the second terminal at the output end of the switch module SW. A turn-on signal may be provided to a control terminal (e.g., a base terminal) of the bypass transistor 121 on the basis of the current output from the switch module SW and the first bypass resistor RB. Accordingly, the bypass transistor 121 may be turned on.

As the bypass transistor 121 is turned on, the input current CIN may be output to an output terminal (e.g., the emitter terminal) via an input terminal (e.g., a collector terminal) of the bypass transistor 121. Accordingly, the input current CIN may be output as an output current COUT after passing through the bypass path.

Referring to FIG. 3, according to the bypass signal BYP, the input current CIN (e.g., the current output from the charging power source 2 or output from the adjacent battery cell 130) is no longer input to the fully charged battery cell 130, so that the voltage of the battery cell can be maintained at a target level. However, according to FIG. 3, the current at an output side of the switch module SW, that is, the current input to the control terminal of the bypass transistor 121 may be only a few tens of mA, making normal bypass operation difficult.

Referring to FIG. 4A, the second bypass module 120b may include an input resistor RA, a first bypass resistor RB, a first bypass transistor 121, and a switch module SW, and may further include a second bypass resistor RC and a second bypass transistor 122. Hereinafter, descriptions overlapping with those described above with reference to FIG. 3 will be omitted.

Referring to FIG. 4A, the switch module SW may receive the bypass signal BYP in a logic high state. In this case, the switch module SW may be turned on and an output end thereof may be conducted. That is, a current path may be formed from an input terminal (e.g., a collector terminal) to an output terminal (e.g., an emitter terminal) of a transistor (e.g., an NPN transistor) included in the switch module SW. For example, the transistor included in the switch module SW and the first bypass transistor 121 may include NPN transistors.

In response to receiving the bypass signal BYP in a logic high state, the switch module SW may draw a current from a control terminal (e.g., a base terminal) of the second bypass transistor 122. The second bypass transistor 122 (e.g., a PNP transistor) may be turned on in response to the drawn current. In this case, the second bypass transistor 122 may operate in a PNP transistor saturation region. Here, the second bypass transistor 122 operates as a current buffer so that the input current CIN may flow through a bypass path that passes through the first bypass transistor 121. The current flowing through the bypass path may be referred to as a bypass current. At this time, the bypass current may flow from an input terminal (e.g., a collector terminal) to an output terminal (e.g., an emitter terminal) of the first bypass transistor 121. In this case, a magnitude of the bypass current may be greater than a magnitude of the input current CIN.

According to the exemplary embodiment of the present disclosure, a magnitude of the current that is output from the switch module SW in FIG. 3 and input to the control terminal of the first bypass transistor 121 may be only a few tens of mA. However, the magnitude of the current input from the second bypass transistor 122 to the control terminal of the first bypass transistor 121 in FIG. 4 may be amplified to several A and input. Accordingly, the magnitude of the bypass current may be amplified to tens of amperes.

Referring to FIG. 4B, the second bypass module 120b may include a capacitor CP. A first end of the capacitor CP may be connected to an output end of the second bypass transistor 122, a control end of the first bypass transistor 121, and the first bypass resistor RB.

As the first bypass transistor 121 is turned on, a voltage of the battery cell 130 may be suddenly decreased, and the capacitor CP is used. The capacitor CP may be a means for preventing the voltage of the battery cell 130 from being suddenly dropped. As the second bypass transistor 122 is turned on, the capacitor CP is charged. At this time, even when the first bypass transistor 121 is turned on and a voltage of the first bypass transistor 121 is instantaneously lowered, a voltage of the capacitor CP may be maintained at a constant value, so that a current (e.g., a base current) of the control terminal of the first bypass transistor 121 through the first bypass resistor RB may be maintained.

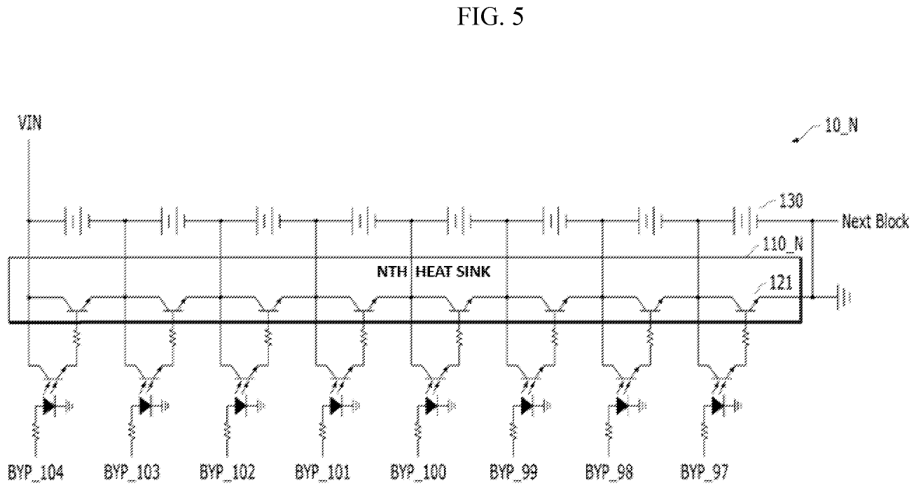

FIG. 5 is a circuit diagram for describing the battery block and the bypass module according to the exemplary embodiment of the present disclosure. Hereinafter, a description will be given with also reference to the reference numerals of FIGS. 1 to 4B.

Referring to FIG. 5, the Nth battery block 10_N is exemplified and described for convenience of description, but, it is apparent that the same technical idea may be applied to the first battery block 10_1 to an (N-1)th battery block 10_N-1.

The Nth battery block 10_N may receive an input voltage VIN generated by charging power from the charging power source 2, and each of the plurality of battery blocks 10_1 to 10_N-1 may receive the input voltage VIN output from the previous battery block 10.

Referring to FIG. 5, at least some of the plurality of battery blocks 10_1 to 10_N may include the first bypass module 120a or the second bypass module 120b. The Nth battery block 10_N may include the first bypass module 120a, or the Nth battery block 10_N may include the second bypass module 120b. That is, although the first bypass module 120a is applied in the illustrated example, of course, the second bypass module 120b may also be applied.

The heat sink 110 may be located on the first bypass transistors 121 of the plurality of bypass modules 120 included in the single battery block 10. In addition, the heat sink 110 may be formed to correspond to the plurality of first bypass transistors 121 corresponding to the plurality of battery cells 130, or the heat sink 110 may be formed to correspond to at least some of the plurality of battery cells 130. That is, the heat sink 110 may cool the heat generated in the first bypass transistors 121 by being located on or physically in contact with upper portions, lower portions, or side surfaces of the first bypass transistors 121, which may be overheated by the bypass current. Preferably, the heat sink 110 is formed on the upper portions of the first bypass transistors 121 so as to be adjacent to the first bypass transistors 121 to facilitate stacking during the process, thereby dissipating the heat from the plurality of first bypass transistors.

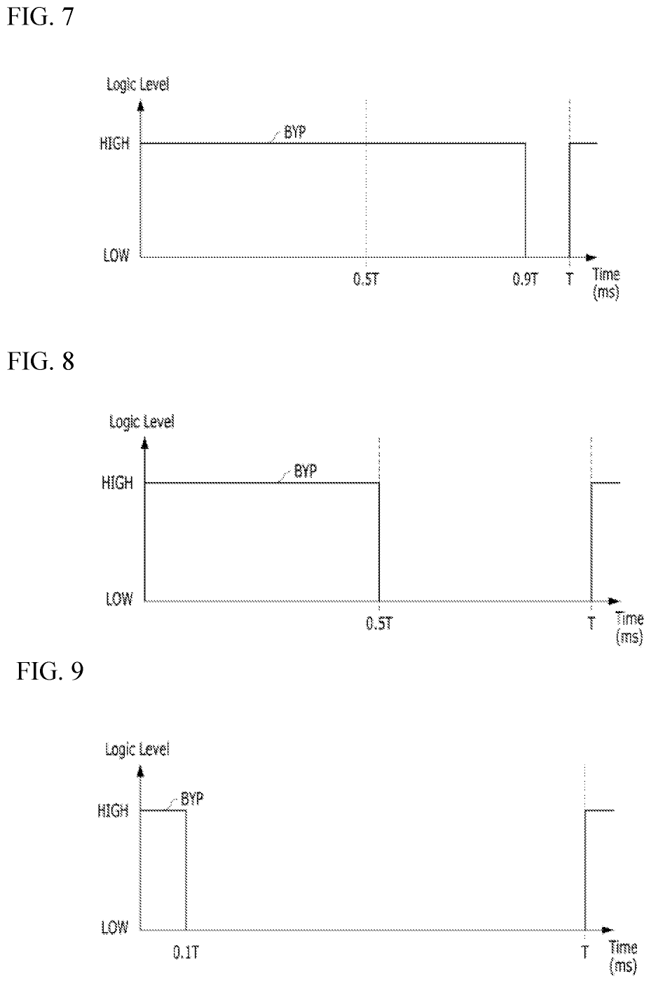

In addition, the first bypass transistors 121 may be turned on according to logic states of a plurality of bypass signals BYP_97 to BYP_104. For example, when a portion of the bypass signals (e.g., BYP_97) is in a logic high state and the remaining bypass signals (e.g., BYP_98 to BYP_104) are in a logic low state, the first bypass transistor 121 corresponding to the portion of the bypass signals is turned on, and the first bypass transistors 121 corresponding to the remaining bypass signals may be turned off. When the first bypass transistor 121 maintains the turn-on state for a long time, heat may accumulate in a specific portion of the heat sink 110 while the bypass current is continuously conducted, and in order to prevent this, the bypass signals BYP may be time-divided and input. This will be described below with reference to FIGS. 7 to 10.

The bypass signals BYP may be generated for each of the battery blocks 10. As an example, the first control logic 140_1 of the first battery block 10_1 may generate a first group of bypass signals BYPs (e.g., BYP_1 to BYP_8), and the Nth control logic 140_N of the Nth battery block 10_N may generate a second group of bypass signals BYPs (e.g., BYP_97 to BYP_104). As another example, the first control logic 140_1 may serve as the master control logic, and generate and output all the bypass signals BYP.

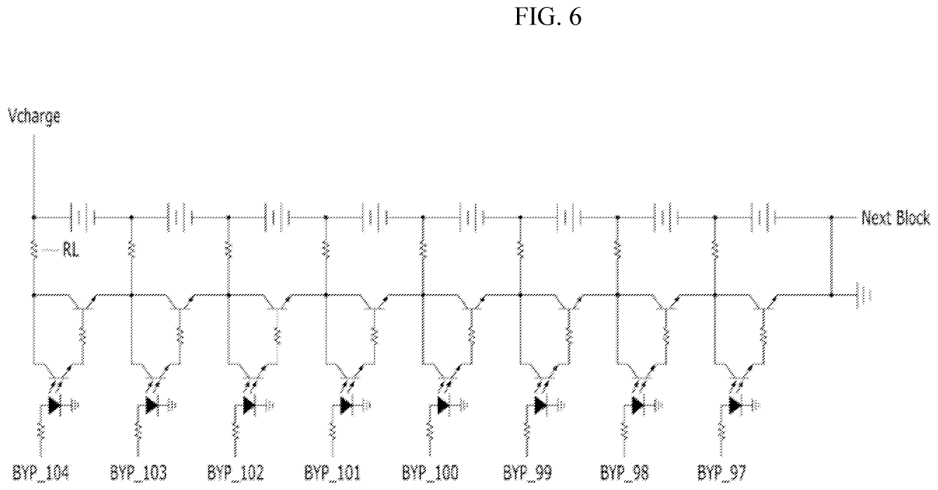

FIG. 6 is a circuit diagram for describing a cell resistor according to a conventional comparative example.

Referring to FIGS. 5 and 6 together, conventionally, a cell resistor RL is provided at one end of the battery cell. When a value of the cell resistor RL is excessively large, power consumption increases, and thus heat is generated, and when the value of the cell resistor RL is excessively small, a bypass current or a total current increases, and thus heat may be extensively generated in elements inside the device. Thus, conventionally, the size of the cell resistor RL is appropriately selected and used, such as, 47 ohms, 51 ohms, or the like. According to the conventional embodiment, the bypass current may be controlled to a magnitude of tens of mA by the appropriately selected cell resistor RL. With the magnitude of the bypass current at that time, cell balance appears to be maintained at an early stage of the use of the battery cells, but as charge and discharge cycles exceed 300 cycles, unbalancing between the battery cells occurs, causing the magnitude of the bypass current to decrease dramatically. Accordingly, the full-charge voltage of 4.2 V is gradually increased, which may lead to destruction or deterioration of the battery cell.

However, according to the exemplary embodiment of the present disclosure, the cell resistor RL between the battery cell and the bypass path may be removed. In order to control heat that is generated as the cell resistor RL is removed, the battery management device 1 may time-divisionally control the bypass signal BYP, which is proposed in FIGS. 7 to 10.

FIGS. 7 to 9 are diagrams for describing bypass signals according to an exemplary embodiment of the present disclosure. Hereinafter, a description will be given with also reference to the reference numerals of FIGS. 1 to 5.

Referring to FIGS. 7 to 9, as the magnitude of the bypass current increases, a period for which the bypass signal BYP remains in a logic high state may be increased. That is, by maintaining the logic high state of the bypass signal BYP for a long time, the current entering the battery cell 130 may be bypassed to the bypass path, thereby protecting the battery cell 130.

Referring to FIG. 7, when the magnitude of the bypass current has a first value, the bypass signal BYP may have a period of 0.8 T. Referring to FIG. 8, when the magnitude of the bypass current has a second value less than the first value, the bypass signal BYP may have a period of 0.5 T. Referring to FIG. 9, when the magnitude of the bypass current has a third value less than the second value, the bypass signal BYP may have a period of 0.1 T.

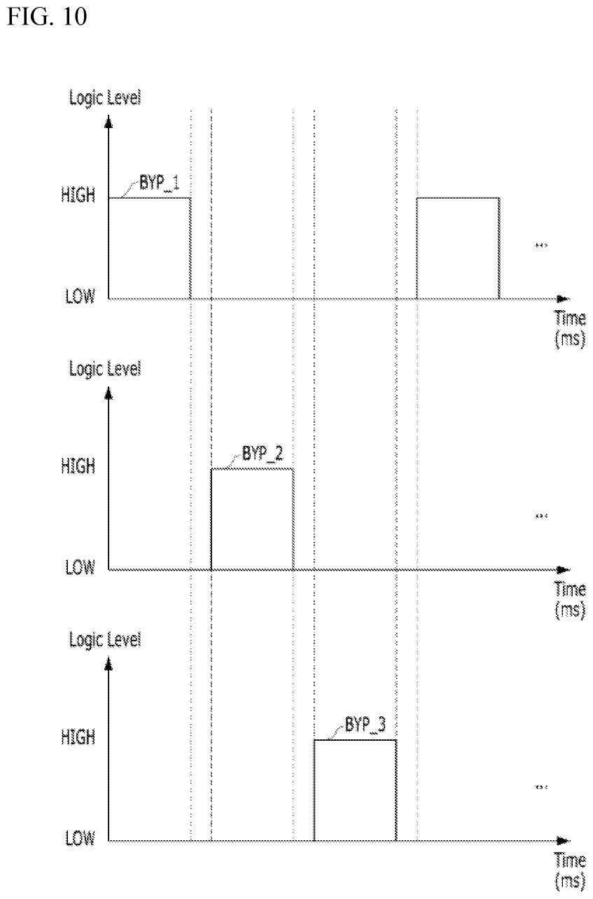

FIG. 10 is a diagram for describing bypass signals according to an exemplary embodiment of the present disclosure.

According to the exemplary embodiment of the present disclosure, when the charging voltage is continuously applied to the battery cells 130, heat may accumulate since the heat sink 110 is shared in each battery block 10. In this case, the control logic 140 may control such that a first bypass signal BYP_1 and a second bypass signal BYP_2 alternately maintain a logic high state. Accordingly, the heat accumulation in the shared heat sink 110 may be prevented.

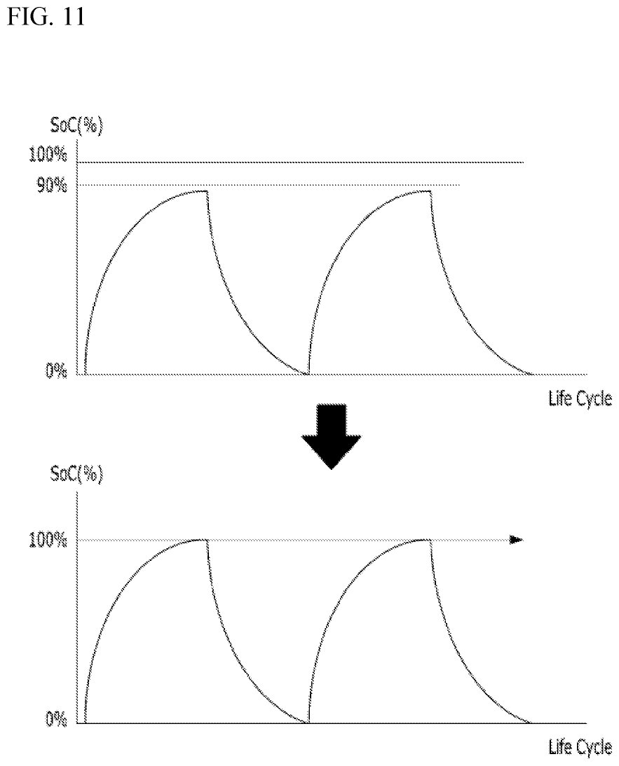

FIG. 11 is a graph for describing a depth of discharge (DoD) cycle according to an exemplary embodiment of the present disclosure.

Referring to FIG. 11, the conventional battery management device operates below a limit line of 80 to 90% due to the fact that the conventional battery management device maintains its lifespan while using 100% DoD, which may cause a fire or explosion when charged to 100%.

However, the battery management device 1 according to the present disclosure completely blocks overvoltage and overheating even during repeated charging and discharging cycles from 0% to 100%, and thus may exhibit the technical effect of being able to operate at 100% DoD. Thus, the battery management device 1 according to the present disclosure may exhibit charging and discharging characteristics that are 10% to 20% superior to those of existing battery management devices.

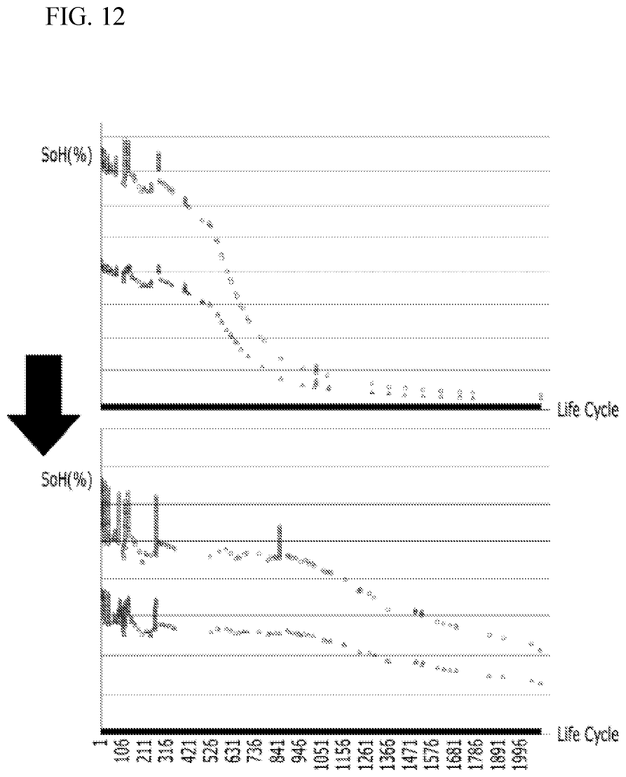

FIG. 12 is a graph for describing a variation of a life cycle according to an exemplary embodiment of the present disclosure.

Specifically, FIG. 12 is a characteristic graph illustrating a state of health (SoH) obtained by performing charging and discharging at 90% DoD while applying heat of 35° to 40° to the battery cell 130.

Referring to an upper graph, in the case of the related art, capacity reduction occurs rapidly after 300 cycles.

However, referring to a lower graph, in the case of the exemplary embodiment of the present disclosure, a contrasting characteristic in which capacity reduction gradually occurs after 900 cycles is shown. That is, according to the exemplary embodiment of the present disclosure, the lifespan of the battery can be increased by delaying capacity reduction by more than 3 times.

The exemplary embodiments are described in the drawings and in the specification as described above. Although the embodiments have been described in the specification by using specific terms, this is only used for the purpose of describing the technical idea of the present disclosure and is not used to limit the scope of the disclosure set forth in the claims. Thus, it will be apparent to those of ordinary skill in the art that various modifications may be made in the embodiments and equivalent embodiments may be derived from the embodiments. Accordingly, the scope of the present disclosure to be protected should be determined by the technical idea defined in the appended claims.

1. A battery management system comprising:
a first bypass transistor including a first terminal electrically and directly connected to a positive electrode of a battery cell and a second terminal electrically and directly connected to a negative electrode of the battery cell, and configured to receive an input by bypassing a current of the battery cell on the basis of a bypass signal; and
a heat sink formed adjacent to the first bypass transistor to cool heat generated in the first bypass transistor.

2. The battery management system of claim 1, wherein the first bypass transistor includes a first conductor formed to directly connect the first terminal to the positive electrode of the battery cell without resistance, and a second conductor formed to directly connect the second terminal to the negative electrode of the battery cell without resistance.

3. The battery management system of claim 2, wherein the first bypass transistor includes a bipolar junction transistor (BJT).

4. The battery management system of claim 1, wherein the heat sink is located on upper portions of a plurality of first bypass transistors included in a battery block and shared by the plurality of first bypass transistors.

5. The battery management system of claim 3, wherein the heat sink cools the generated heat through a time-divided control signal having a logic high or logic low state input to the first bypass transistor.

6. The battery management system of claim 1, further comprising a control logic that controls to detect a heat generation amount of the heat sink, and block all charging currents connected in series in the battery management system when the heat generation amount exceeds a reference value.

7. A battery management device comprising:
a heat sink formed to correspond to at least some of a plurality of battery cells; and
a bypass module configured to conduct a bypass current, which bypasses the battery cells, during charging of the at least some of the plurality of battery cells, and amplify a magnitude of the bypass current in response to a bypass signal in a logic high state.

8. The battery management device of claim 7, wherein the bypass module further includes a switch module that is turned on in response to the bypass signal in the logic high state, and a first bypass transistor configured to form a bypass current path in response to the switch module being turned on.

9. The battery management device of claim 8, further comprising a second bypass transistor configured to receive a current that is input to the bypass module, and amplify a magnitude of the current in response to the first bypass transistor being turned on.

10. The battery management device of claim 9, wherein
the second bypass transistor is a PNP transistor, and
the switch module and the first bypass transistor are NPN transistors.

11. The battery management device of claim 8, wherein the switch module is a photocoupler that physically separates the bypass current path from a current path from which the bypass signal is received.

12. The battery management device of claim 7, further comprising a control logic configured to output a first bypass signal to a first bypass module corresponding to a first battery cell, and to output a second bypass signal in a state inverted from the first bypass signal to a second bypass module corresponding to a second battery cell adjacent to the first battery cell.

13. A battery management device comprising:
a heat sink formed to correspond to at least some of a plurality of battery cells;
a bypass module configured to conduct a bypass current, which bypasses the battery cells, during charging of the at least some of the plurality of battery cells on the basis of a bypass signal; and
a control logic configured to output a first bypass signal to a first bypass module corresponding to a first battery cell, and to output a second bypass signal in a state inverted from the first bypass signal to a second bypass module corresponding to a second battery cell adjacent to the first battery cell.

14. A battery management device comprising a control logic configured to bypass a charging current prior to entering full charge when a charging voltage of a first battery cell in a first battery block is higher than a charging voltage of a second battery cell in a second battery block connected in series to the first battery block to prevent thermal runaway of a heat sink included in the first battery block and shared by a plurality of battery cells, wherein the thermal runaway is caused by simultaneously heating the plurality of battery cells when the plurality of battery cells included in the first battery block simultaneously reach a full-charge voltage.

15. The battery management device of claim 14, wherein
when the first battery cell, the second battery cell, and the plurality of battery cells are lithium-ion battery cells, the full-charge voltage is 4.0 V to 4.4 V,
when the first battery cell, the second battery cell, and the plurality of battery cells are lithium-iron-phosphate battery cells, the full-charge voltage is 3.4 V to 3.8 V, and
the control logic operates the plurality of battery cells normally by preventing the thermal runaway caused by the simultaneous heating.
